(19) United States
(12) Patent Application Publication
(10) Pub. No.: US 2026/0231453 A1
(43) Pub. Date: Aug. 6, 2026

(54) MULTI-GATE FIELD EFFECT TRANSISTORS AND METHODS OF FABRICATION THEREOF

(71) Applicant: TAIWAN SEMICONDUCTOR MANUFACTURING COMPANY, LTD., Hsinchu (TW)

(72) Inventors: Yu-Hsien CHIANG, Hsinchu (TW); Zheng Hui LIM, Hsinchu (TW); Yu-Chang LIN, Hsinchu (TW); Ji-Yin TSAI, Hsinchu (TW); Ku-Feng YANG, Hsinchu (TW); Pei-Ren JENG, Hsinchu (TW); Szuya LIAO, Hsinchu (TW)

(21) Appl. No.: 19/044,048

(22) Filed: Feb. 3, 2025

(51) Int. Cl. H10D 30/01; H01L 21/02; H10D 30/00

(52) U.S. Cl. CPC H10D 30/0193; H10D 30/502; H10P 14/3816

(57) ABSTRACT

Embodiments of the present disclosure provide a method of forming channel stacks for multi-channel devices using laser recrystallization technology. By using laser recrystallization, sacrificial layers in the channel stack may be oxide containing layers, instead of epitaxial layer, i.e. SiGe sacrificial layers. By avoiding SiGe sacrificial layers, Ge segregation to adjacent semiconductor channel layers may be reduced during thermal processing. Tensile strain caused by SiGe sacrificial layers to the Si channel layers may also be reduced. Additionally, embodiments of the present disclosure enable different crystalline orientations in p-channels and n-channels in the CFETs, therefore, improving device performance.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge.

In pursuit of higher device density, higher performance, and lower costs, challenges from both fabrication and design issues have resulted in the development of three-dimensional designs, such as a multi-gate field effect transistor (FET), including a nanosheet FET. In a nanosheet FET, all side surfaces of the channel are surrounded by the gate electrode, which allows for fuller depletion in the channel and results in less short-channel effects and better gate control. As transistor dimensions are continually scaled down, further improvements of the nanosheet FET are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1P schematically illustrate various stages of fabricating vertically stacked complementary field effect transistors (CFETs) according to some embodiments of the present disclosure.

FIGS. 2A-2B schematically illustrate profiles of semiconductor composition across channels in multi-channel transistors according to embodiments of the present disclosure.

FIGS. 3A-3D schematically illustrate various stages of fabricating vertically stacked complementary field effect transistors (CFETs) according to some embodiments of the present disclosure.

FIGS. 4A-4I schematically illustrate various stages of fabricating vertically stacked complementary field effect transistors (CFETs) according to some embodiments of the present disclosure.

FIGS. 5A-5E schematically illustrate various stage of fabricating a gate-all-around field effect transistor according to embodiments of the present disclosure.

FIGS. 6A-6C schematically illustrate various stage of fabricating a gate-all-around field effect transistor according to embodiments of the present disclosure.

### DETAILED DESCRIPTION

following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure provide methods of forming a channel stack, which includes alternating semiconductor channel layers and sacrificial layers, for multi-channel devices, such as vertically stacked complementary field effect transistors (CFETs), non-stacked CFETs, or the like. Particularly, embodiments of the present disclosure provide a channel stack including epitaxial semiconductor channel layers formed using technology of solid-phase epitaxy recrystallization.

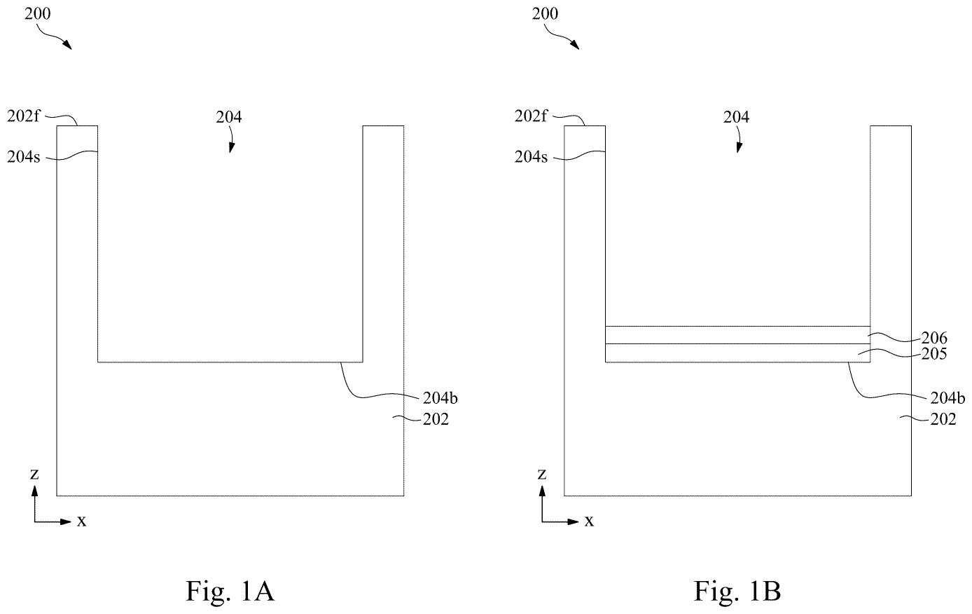

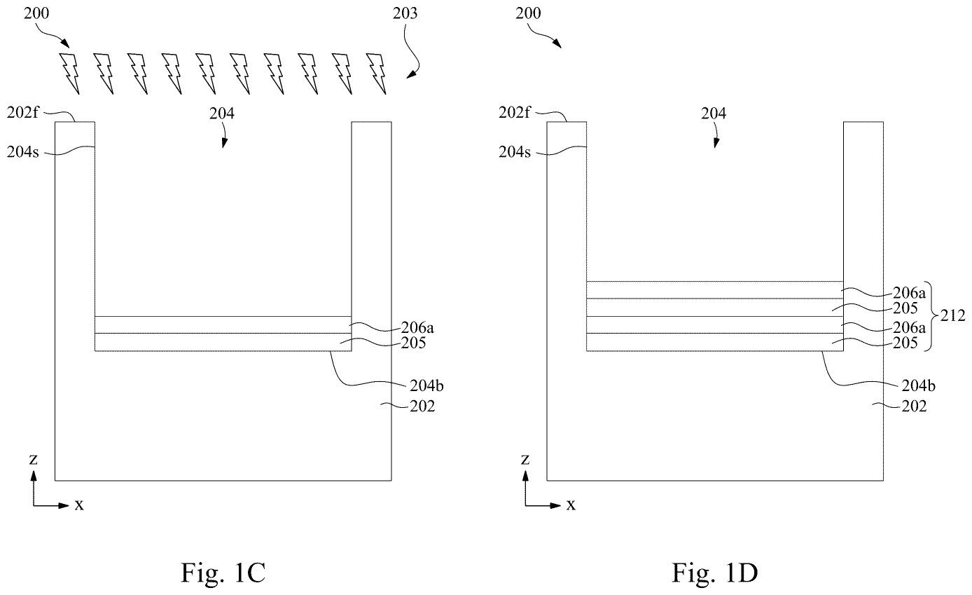

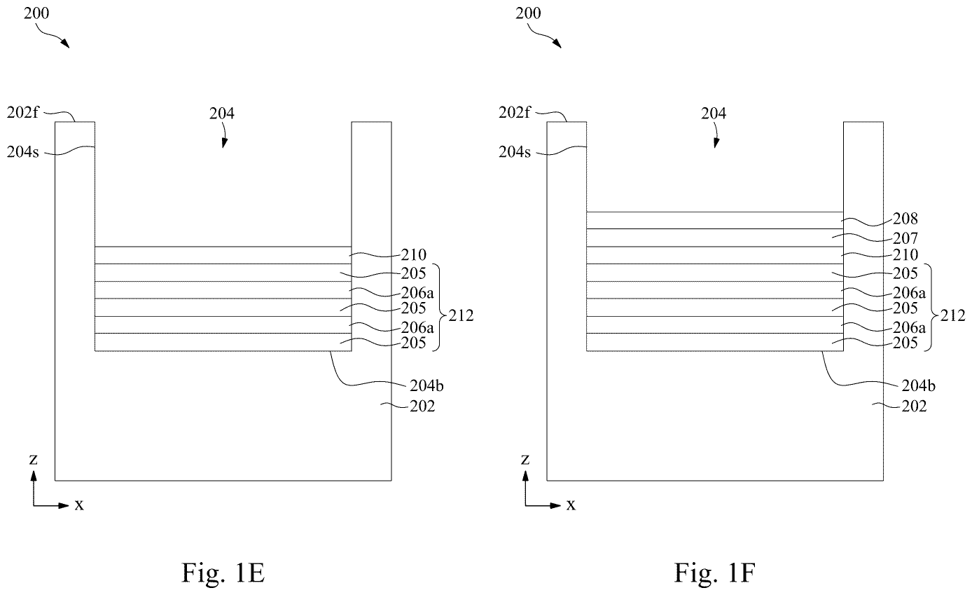

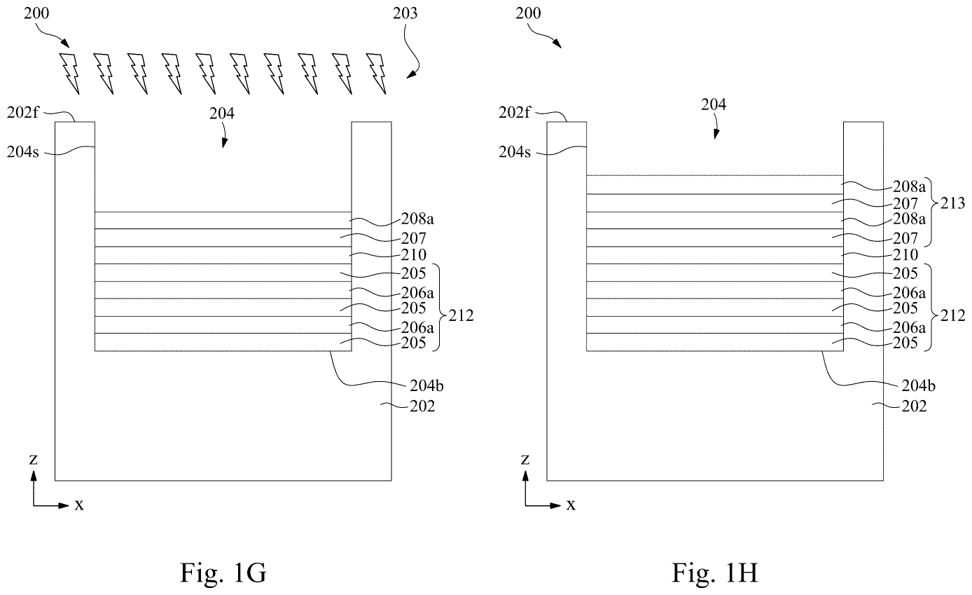

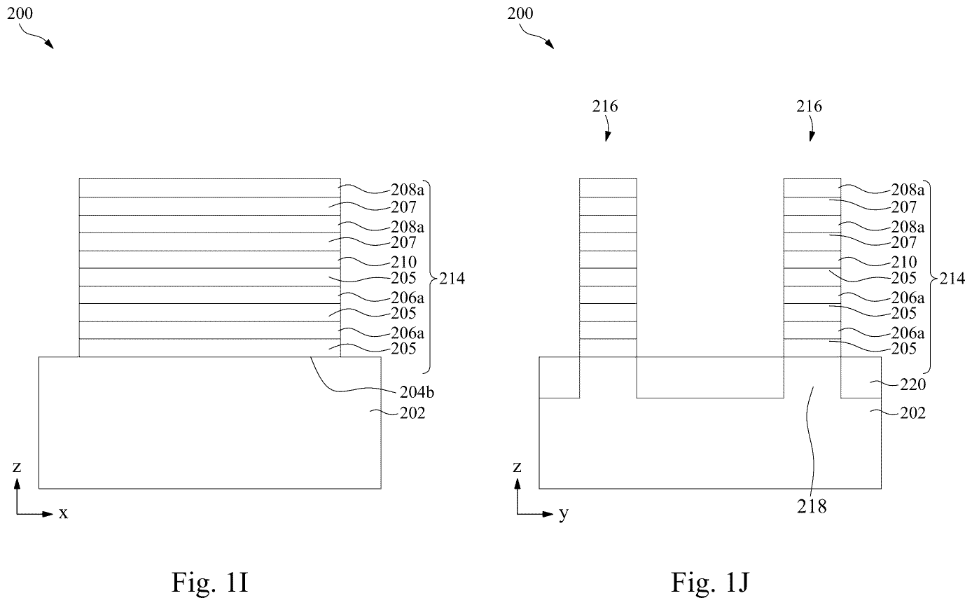

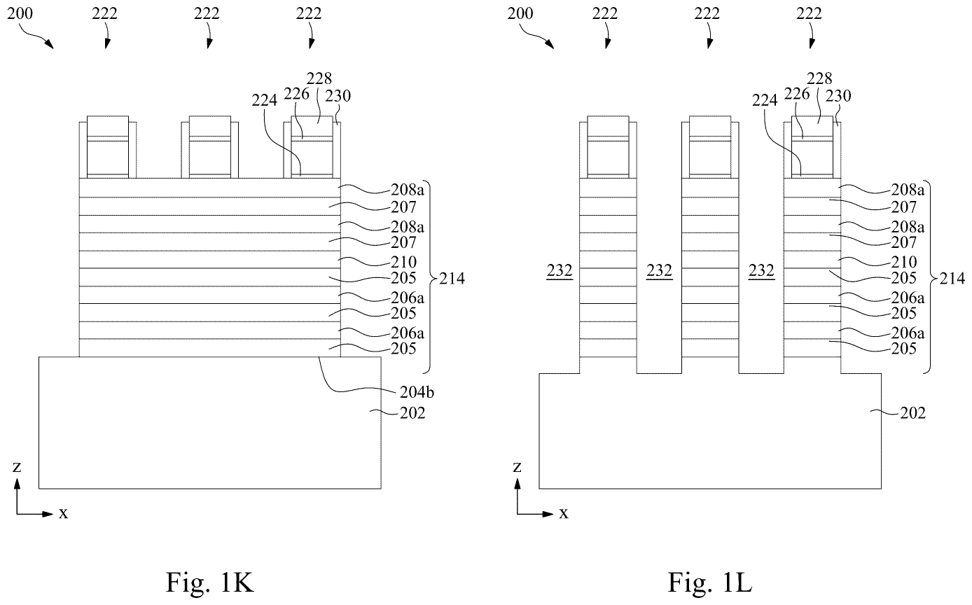

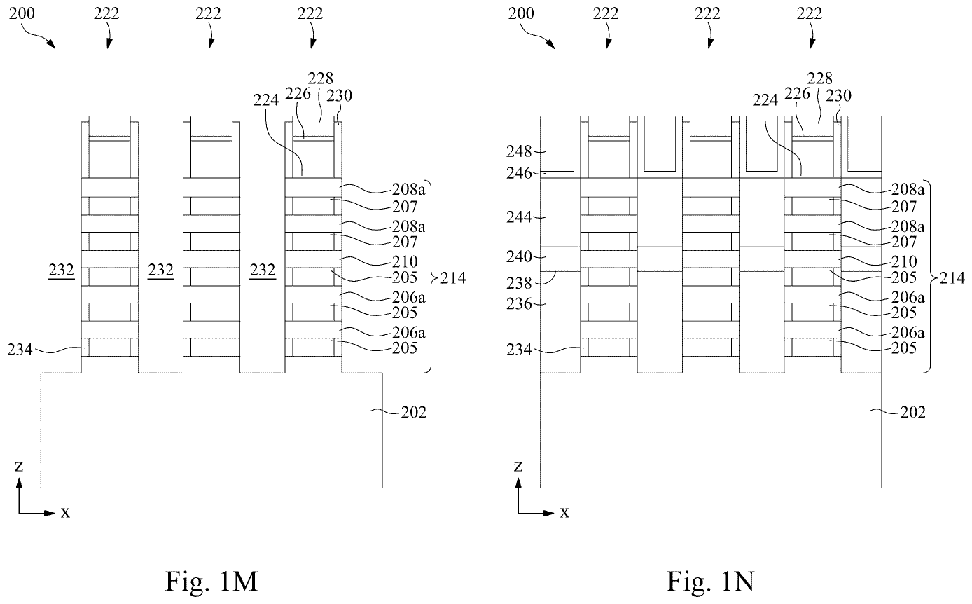

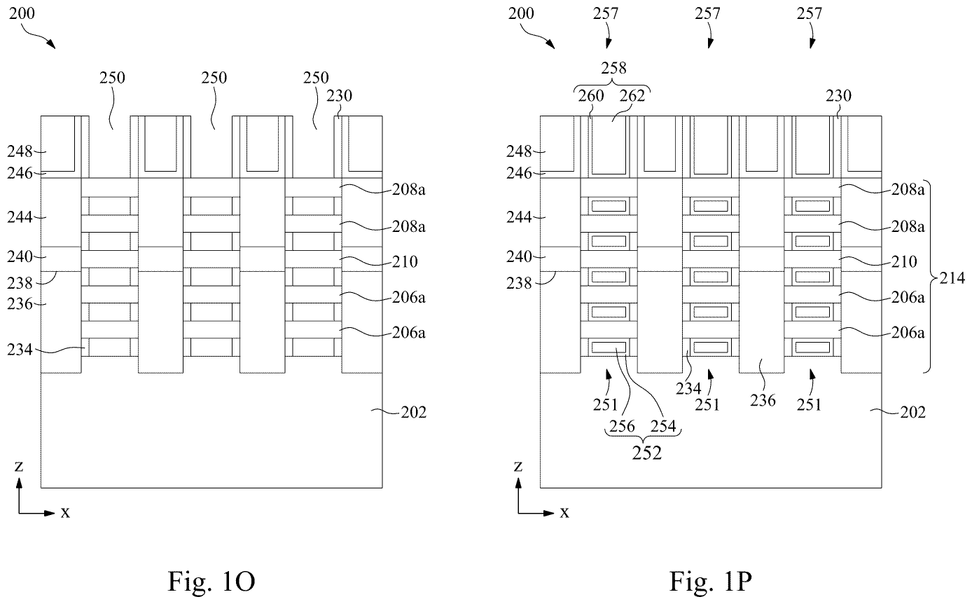

FIGS. 1A-1P schematically illustrate various stages of fabricating a semiconductor structure 200 including a channel stack for vertically stacked complementary field effect transistors (CFETs) according to some embodiments of the present disclosure. FIGS. 1A-1J are cross-sectional views of the semiconductor structure 200 at various stages.

FIG. 1A is a schematic cross-sectional view of a substrate 202 on which a channel stack is to be formed. The substrate 202 may be a semiconductor substrate configured to have semiconductor devices formed thereon. The substrate 202 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiment, the substrate 202 is made of silicon. In some embodiments, the substrate 202 is a silicon-on-insulator (SOI) substrate having an insulating layer (not shown) disposed between two silicon layers for enhancement. In one aspect, the insulating layer is an oxygen-containing layer.

In some embodiments, the substrate 202 may include a single crystalline semiconductor material and a front surface 202f of the substrate 202 has a crystalline orientation, which is selected to achieve desired mobility in the channels to be formed. In some embodiments, the crystalline orientation of the substrate 202 is selected to achieve most mobility for the corresponding FETs to be formed thereon. For example, the front surface 202f of the substrate 202 is on a (110) plane to achieve improved hole mobility or on a (100) plane to achieve improved electron mobility. In some embodiments, the substrate 202 is a crystalline silicon substrate and the front surface 202f is on a (100) plane.

In some embodiments, a stack cavity 204 is formed from a front surface 202f of the substrate 202. The stack cavity 204 is sized to have a channel stack within. In some embodiments, the stack cavity 204 may have a rectangular shape in a top view or in x-y plane. In some embodiments, the stack cavity 204 may have a length along the x-direction in a range between about 500 nm and about 5000 nm, and a width along the y-direction (into the paper in FIG. 1A) in a range between about 500 nm and about 5000 nm. The stack cavity 204 may have a depth along the z-direction in a range between about 60 nm and 200 nm.

The stack cavity 204 has a bottom surface 204b and sidewalls 204s. The bottom surface 204b has the same crystalline orientation as the front surface 202f. As discussed below, the sidewalls 204s may be used as a seed layer for recrystallization of channel layers to be formed. In some embodiments, the sidewalls 204s may be oriented to enable crystallization of the channel layers in predetermined crystalline orientation. For example, the sidewalls 204s parallel to the x-z plane is on a (100) crystalline orientation, and the sidewalls 204s parallel to the y-z plane is on a (110) crystalline orientation.

In FIG. 1B, a first sacrificial layer 205 is formed on the bottom surface 204b of the stack cavity 204. In some embodiments, the first sacrificial layer 205 may include an oxide material, for example silicon oxide (SiO₂). The first sacrificial layer 205 serves to define a space for a gate stack around a channel region and is eventually removed. In some embodiments, the first sacrificial layer 205 has a thickness along the z-direction in a range between about 3 nm and about 10 nm. The first sacrificial layer 205 may be deposited by any suitable process, such as chemical vapor deposition (CVD), atomic layer deposition (ALD), or the like. In some embodiments, the first sacrificial layer 205 is formed by a bottom-up deposition so that the sidewall 204s above the first sacrificial layer 205 remain exposed to the stack cavity 204.

Further as shown in FIG. 1B, a first channel layer 206 is formed on the first sacrificial layer 205. The first channel layer 206 includes semiconductor materials suitable to function as a channel layer. In some embodiments, the first channel layer 206 has a thickness along the z-direction in a range between about 3 nm and about 15 nm. The first channel layer 206 include semiconductor materials, such as Si, SiGe, Ge, SiC, GeAs, GaP, InP, InAs, InSb, GaAsP, AlInAs, AlGaAs, InGaAs, GaInP, GaInAsP, or any combinations thereof. In some embodiments, the first channel layer 206 is made of SiGe, with Ge concentration in a range between about 15% and about 35%. The first channel layer 206 may be deposited in an amorphous form. The amorphous semiconductor deposition process may be carried out in a LPCVD reactor, in a temperature between about 360° C. to 560° C., for example about 400° C.

In some embodiments, the first channel layer 206 is formed by a bottom-up deposition, as shown in FIG. 1B. The first channel layer 206 is in contact with the sidewalls 204s of the channel cavity 204. Therefore, edge regions of the first channel layer 206, which are formed in amorphous form, are in contact with the crystalline surface of the substrate 202 at the sidewalls 204s.

After formation of the amorphous first channel layer 206, a solid phase epitaxial recrystallization (SPER) process is performed to convert the first channel layer 206 to a crystalline state, as shown in FIG. 1C. In some embodiments, the SPER process is performed by a laser anneal process. In some embodiments, a laser source 203 is applied to the first channel layer 206 to rapidly raise the temperature of the first channel layer 206 to a temperature level between about 1200° C. to about 1400° C. In some embodiments, the laser source 203 may be pulsed for a short duration, for example for a duration in a range between about 100 ns and 500 ns, such as about 160 ns. By rapidly raise the temperature for a short duration, the first channel layer 206 is annealed to a crystalline state while still in the solid phase, annotated as the first channel layer 206a.

Because the first channel layer 206 is in contact with the sidewalls 204s, the crystalline structures of the substrate 202 on the sidewalls 204s serve as seed layers for the recrystallization of the first channel layer 206a. Therefore, the crystalline orientation of the first channel layer 206a may be the same as the substrate 202.

Depending on the number of channels in the device structure, additional pairs of first sacrificial layer 205 and first channel layer 206a may be formed in the stack cavity 204, as shown in FIG. 1D. The same processes, i.e. deposition of a first sacrificial layer 205, deposition of a first channel layer 206, and SPER recrystallization, may be repeated to form each pair of first sacrificial layer 205 and first channel layer 206a. The pairs of first sacrificial layer 205 and first channel layer 206a form a first channel stack 212. In FIG. 1D, two pairs of first sacrificial layer 205 and first channel layer 206a are shown in the first channel stack 212 as an example. In some embodiments, the first channel stack 212 may include two to ten pairs of first sacrificial layer 205 and first channel layer 206a.

As discussed, the semiconductor structure 200 to be formed includes a complementary FET (CFET) in which two or more nanosheet FETs are vertically stacked on top of one another. The pairs of first sacrificial layer 205 and first channel layer 206a are designated for a first type of FET, such as P-FET.

In FIG. 1E, a first sacrificial layer 205 and an inter-transistor dielectric layer 210 are formed over the pairs of the first sacrificial layer 205 and first channel layer 206a. The inter-transistor dielectric layer 210 functions to isolate gate structure around the first channel layers 206a from the gate structure above. In some embodiments, the inter-transistor dielectric layer 210 may be low-k dielectric material having etch selectivity with the first sacrificial layers 205. In some embodiments, the inter-transistor dielectric layer 210 may include silicon oxy-carbon-nitride (SiOCN), silicon carbon-nitride (SiCN), silicon oxide, silicon nitride, or the like. In some embodiments, the inter-transistor dielectric layer 210 may be formed by a suitable deposition method, such as chemical vapor deposition (CVD), plasma-enhanced CVD (PECVD), or the like. In some embodiments, the inter-transistor dielectric layer 210 has a thickness along the z-direction in a range between about 3 nm and about 15 nm.

After formation of the inter-transistor dielectric layer 210, two or more pairs of a second sacrificial layer 207 and a second channel layer 208 may be sequentially formed over the inter-transistor dielectric layer 210, as shown in FIGS. 1F, 1G, and 1H.

In FIG. 1F, a second sacrificial layer 207 is formed on inter-transistor dielectric layer 210. In some embodiments, the second sacrificial layer 207 may include an oxide material, for example silicon oxide (SiO₂). In some embodiments, the second sacrificial layer 207 and the first sacrificial layer 205 include the same material. The second sacrificial layer 207 serves to define a space for a gate stack around the second channel layer 208 and is eventually removed. In some embodiments, the second sacrificial layer 207 has a thickness along the z-direction in a range between about 3 nm and about 10 nm. The second sacrificial layer 207 may be deposited by any suitable process, such as chemical vapor deposition (CVD), atomic layer deposition (ALD), or the like. In some embodiments, the seconds sacrificial layer 207 is formed by a bottom-up deposition so that the sidewall 204s above the second sacrificial layer 207 remain exposed to the stack cavity 204.

Further as shown in FIG. 1F, a second channel layer 208 is formed on the second sacrificial layer 207. The second channel layer 208 includes semiconductor materials suitable to function as a channel layer. In some embodiments, the second channel layer 208 has a thickness along the z-direction in a range between about 3 nm and about 15 nm. The second channel layer 208 include semiconductor materials, such as Si, SiGe, Ge, SiC, GeAs, GaP, InP, InAs, InSb, GaAsP, AlInAs, AlGaAs, InGaAs, GaInP, GaInAsP, or any combinations thereof. In some embodiments, the second channel layer 208 is made of silicon. The second channel layer 208 may be deposited in an amorphous form. The amorphous semiconductor deposition process may be carried out in a LPCVD reactor, in a temperature between about 360° C. to 560° C., for example about 400° C.

In some embodiments, the second channel layer 208 is formed by a bottom-up deposition, as shown in FIG. 1F. The second channel layer 208 is in contact with the sidewalls 204s of the channel cavity 204. Therefore, edge regions of the second channel layer 208, which are formed in amorphous form, are in contact with the crystalline surface of the substrate 202 at the sidewalls 204s.

After formation of the amorphous second channel layer 208, a solid phase epitaxial recrystallization (SPER) process is performed to convert the second channel layer 208 to a crystalline state, as shown in FIG. 1G. In some embodiments, the SPER process is performed by a laser anneal process. In some embodiments, a laser source 203 is applied to the second channel layer 208 to rapidly raise the temperature of the second channel layer 208 to a temperature level between about 1200° C. to about 1400° C. In some embodiments, the laser source 203 may be pulsed for a short duration, for example for a duration in a range between about 100 ns and 500 ns, such as about 160 ns. By rapidly raise the temperature for a short duration, the second channel layer 208 is annealed to a crystalline state while still in the solid phase, annotated as the second channel layer 208a.

Because the second channel layer 208 is in contact with the sidewalls 204s, the crystalline structures of the substrate 202 on the sidewalls 204s serve as seed layers for the recrystallization of the second channel layer 208a. Therefore, the crystalline orientation of the second channel layer 208a may be the same as the substrate 202 and the first channel layer 206a.

Depending on the number of channels in the device structure, additional pairs of second sacrificial layer 207 and second channel layer 208a may be formed in the stack cavity 204, as shown in FIG. 1H. The same processes, i.e. deposition of a second sacrificial layer 207, deposition of a second channel layer 208, and SPER recrystallization, may be repeated to form each pair of second sacrificial layer 207 and second channel layer 208a. The pairs of second sacrificial layer 207 and second channel layer 208a form a second channel stack 213. In FIG. 1H, two pairs of second sacrificial layer 207 and second channel layer 208a are shown in the second channel stack 213 as an example. In some embodiments, the second channel stack 213 may include two to ten pairs of second sacrificial layer 207 and second channel layer 208a. In some embodiments, the number of first channel layers 206a and the number of second channel layers 208a are the same.

The sidewall portions of the substrate 202 is then removed and a channel stack 214 is formed over the substrate 202, as shown in FIG. 1I. The channel stack 214 is configured to be channel regions of vertically stacked CFETs.

After formation of the channel stack 214, fin structures 216 are formed from the channel stack 214 and the substrate 202, as shown in FIG. 1J. FIG. 1J is a cross-sectional view of the semiconductor structures along the z-y plane, or the y-cut. Each fin structure 216 has an upper portion including the channel stack 214 and a well portion 218 formed from the substrate 202. The fin structures 216 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structures 216 by etching the complementary channel stack 214 and the substrate 202a. The etch process can include dry etch, wet etch, reactive ion etch (RIE), and/or other suitable processes.

The fin structures 216 are formed along the direction of the channel so that portions of the fin structures 216 become channels of the subsequently formed FETs. An isolation region 220 may be formed by deposition an insulation material in the trenches between the fin structures 216. The insulating material may be made of an oxygen-containing material, such as silicon oxide or fluorine-doped silicate glass (FSG); a nitrogen-containing material, such as silicon nitride, silicon oxynitride (SiON), SiOCN, SiCN; a low-k dielectric material; or any suitable dielectric material. The insulating material may be formed by any suitable method, such as low-pressure chemical vapor deposition (LPCVD), plasma enhanced CVD (PECVD) or flowable CVD (FCVD). A planarization operation, such as a chemical mechanical polishing (CMP) process and/or an etch-back process, is performed such that the tops of the fin structures 216 are exposed from the insulating material. The insulating material may be recessed by removing a portion of the insulating material located between adjacent fin structures 216 to form the isolation region 220, which may be the shallow trench isolation (STI).

In FIG. 1K, sacrificial gate structures 222 are formed over the fin structures 216. The sacrificial gate structures 222 are formed over a portion of the fin structures 216. Each sacrificial gate structure 222 may include a sacrificial gate dielectric layer 224, a sacrificial gate electrode layer 226, and a mask layer 228. The sacrificial gate dielectric layer 224, the sacrificial gate electrode layer 226, and the mask layer 228 may be formed by sequentially depositing blanket layers of the sacrificial gate dielectric layer 224, the sacrificial gate electrode layer 226, and the mask layer 228, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

Sidewall spacers 230 are formed on sidewalls of the sacrificial gate structures 222. The sidewall spacers 230 may be formed by first depositing a conformal layer that is subsequently etched back to form the sidewall spacers 230. For example, a spacer material layer can be disposed conformally on the exposed surfaces of the semiconductor structure 200. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fin structures 216, leaving the sidewall spacers 230 on the vertical surfaces, such as the sidewalls of sacrificial gate structures 222. The sidewall spacers 230 may be made of a dielectric material such as silicon oxide, silicon nitride, silicon carbide, silicon oxynitride, SiCN, silicon oxycarbide, SiOCN, and/or combinations thereof.

In FIG. 1L, the fin structures 216 that are exposed on opposite sides of the sacrificial gate structure 222 and the sidewall spacers 230 are recessed to form source/drain recesses 232. The exposed portions of the fin structures 216 are selectively recessed by using one or more suitable etch processes, such as dry etch, wet etch, or a combination thereof. In some embodiments, exposed portions of the complementary channel stack 214 of the fin structures 216 are removed, exposing portions of the well portions 218.

In FIG. 1M, inner spacers 234 are formed. Edge portions of the first sacrificial layers 205 and the second sacrificial layers 207 of the channel stack 214 are removed horizontally along the X direction. The removal of the edge portions of the first sacrificial layers 205 and the second sacrificial layers 207 form cavities in the fin structures 216 under the sidewall spacers 230. A dielectric layer is filled in the cavities to form the inner spacers 234. The inner spacers 234 may be made of a low-K dielectric material, such as SiON, SiCN, SiOC, SiOCN, or SiN. The inner spacers 234 may be formed by first forming a conformal dielectric layer using a conformal deposition process, such as ALD, followed by an etching to remove portions of the conformal dielectric layer other than the inner spacers 234. The etch process may be mainly an isotropic etch or a combination of isotropic etch and anisotropic etch to remove the dielectric layer deposited on sidewall and bottom respectively.

In FIG. 1N, first source/drain regions 236 and second source/drain regions 244 are formed in the source/drain recesses 232. The first source/drain regions 236 are epitaxial features grown from exposed semiconductor surfaces of the well portion 218 of the fin structures 216 and the first channel layers 206a.

The first source/drain regions 236 and second source/drain regions 244 may include one or more layers of Si, SiP, SiC and SiCP for an n-channel FET or Si, SiGe, Ge for a p-channel FET. In some embodiments, the first source/drain regions 236 includes one or more layers of Si, SiGe, Ge for a p-channel FET. In some embodiments, the second source/drain regions 244 includes one or more layers of Si, SiP, SiC and SiCP for a n-channel FET.

The first source/drain regions 236 may be grown from the first channel layers 206a. The first source/drain regions 236 may grow both vertically and horizontally to form facets, which may correspond to crystalline planes of the material used for the first channel layers 206a. The first source/drain regions 236 may be formed by an epitaxial growth method using CVD, ALD or MBE.

The source/drain regions 236 are formed in lower portions of the source/drain recesses 232. A first contact etch stop layer (CESL) 238 and a first interlayer dielectric (ILD) layer 240 are formed over the first source/drain regions 236. The first CESL 238 may be conformally formed on the exposed surfaces of the semiconductor device 200. The first CESL 238 covers the first source/drain regions 236, the sidewall spacers 230, the isolation region 220, and the exposed surface of the channel stack 204. The first CESL 238 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, the first ILD layer 240 is formed on the first CESL 238 over the semiconductor structure 200. The materials for the first ILD layer 240 may include tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials comprising Si, O, C, and/or H. The first ILD layer 240 may be deposited by a PECVD process or other suitable deposition technique. In some embodiments, after formation of the first ILD layer 240, the semiconductor device 200 may be subject to a thermal process to anneal the first ILD layer 240.

In some embodiments, an etch back process may be performed so that a top surface of the first CESL 238 and the first ILD layer 240 below the topmost second channel layers 208a so that the second channel layers 208a are exposed to the source/drain recesses 232.

The second source/drain regions 244 are epitaxial features grown from exposed semiconductor surfaces of the second channel layers 208a. The second source/drain regions 244 may grow both vertically and horizontally to form facets, which may correspond to crystalline planes of the material used for the second channel layers 208a. The second source/drain regions 244 may be formed by an epitaxial growth method using CVD, ALD or MBE.

A second CESL 246 and a second ILD layer 248 are formed over the second source/drain regions 244. The second CESL 246 may be conformally formed on the exposed surfaces of the semiconductor device 200. The second CESL 246 covers the second source/drain regions 244, the sidewall spacers 230, and the first ILD layer 240.

After the second ILD layer 248 is formed, a planarization operation, such as CMP, is performed on the semiconductor device 200 to remove portions of the second ILD layer 248, the second CESL 246 and the sacrificial gate electrode layer 226 is exposed. The sacrificial gate structures 222 and the sacrificial layers 205 are removed, as shown in FIG. 1O. The removal of the sacrificial gate structure 222 forms gate recesses 250 between the sidewall spacers 230 and exposes the portions of the complementary channel stack 214 below the sacrificial gate structure 223. The sacrificial semiconductor layers 205, 207 may then be selectively removed to expose the channel layers 206a, 208a.

In FIG. 1P, first replacement gate structures 252 and second replacement gate structures 258 are formed around the first channel layers 206a and second semiconductor layers 206b respectively.

The first replacement gate structures 252 include a first gate dielectric layer 254 formed around the first channel layers 206a, and a first gate electrode layer 256 deposited over the first gate dielectric layer 254. The first replacement gate structures 252, the first channel layers 206a, and the first source/drain regions 236 form first transistors 251. The first channel layers 206a connect between the first source/drain regions 236 and function as nanosheet channels of the first transistors 251.

The second replacement gate structures 258 are formed around the second channel layers 208a. The second replacement gate structures 258 include a second gate dielectric layer 260 formed around the second channel layers 208a, and a second gate electrode layer 262 deposited over the second gate dielectric layer 260. The second replacement gate structures 258, the second channel layers 208a, and the second source/drain regions 244 form second transistors 257. The second channel layers 208a connect between the second source/drain regions 244 and function as nanosheet channels of the second transistors 257.

In some embodiments, the first gate dielectric layer 254 and the second gate dielectric layer 260 are formed at the same time. The first gate dielectric layer 254 is deposited on the exposed surfaces of the first channel layers 206a. The second gate dielectric layer 260 is deposited on the exposed surfaces of the second channel layers 208a. In some embodiments, the first gate dielectric layer 254 and the second gate dielectric layer 260 may include a high-k dielectric material. In some embodiments, the first gate dielectric layer 254 and the second gate dielectric layer 260 may be formed by conformal processes.

The first gate electrode layer 256 is then formed in the gate recesses 250 and on the first gate dielectric layer 254. The first gate electrode layer 256 is formed on the first gate dielectric layer 254 to surround the first channel layer 206a. The first gate electrode layer 256 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The first gate electrode layer 256 may be formed by PVD, CVD, ALD, electro-plating, or other suitable method.

In some embodiments, the first gate electrode layer 256 includes p-type gate electrode layer such as TiN, TaN, TiTaN, TiAlN, WCN, W, Ni, Co, or other suitable material, and the first gate electrode layer 256 is a gate electrode layer of a PFET.

In some embodiments, an etch back process is performed after deposition of the first electrode layer 254 such that the first replacement gate structure 252 remains at a lower portion of the gate recesses 250.

The second gate electrode layer 262 is formed in the gate recesses 250 and on the second gate dielectric layer 260. The second gate electrode layer 262 is formed on the second gate dielectric layer 260 to surround the second channel layer 208a. The second gate electrode layer 262 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the second gate electrode layer 262 includes an n-type gate electrode layer such as TiAlC, TaAlC, TiSiAlC, TiC, TaSiAlC, or other suitable material, and the second gate electrode layer 262 is a gate electrode layer of an NFET. The second gate electrode layer 262 may be formed by PVD, CVD, ALD, electro-plating, or other suitable method.

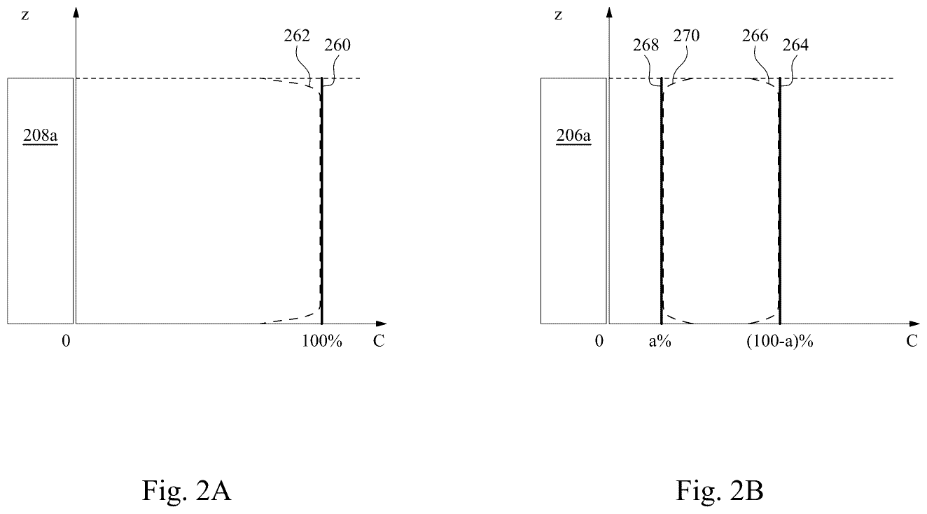

By using SPER technology to form epitaxial channel layers, the semiconductor device according to the present disclosure reduces intermixing between channel layers and sacrificial epitaxial layers, for example SiGe layers. FIGS. 2A-2B schematically illustrate profiles of semiconductor composition across channels in multi-channel transistors according to embodiments of the present disclosure.

In FIG. 2A, profile 260 schematically illustrates silicon concentration of the second channel layer 208a along the z-direction. Profile 262 schematically illustrates silicon concentration of an epitaxial silicon channel layer formed between two epitaxial SiGe layers. As shown by the profile 262, the silicon concentration decreases near the top and bottom surfaces of the channel. The decrease may be caused by intermixing of Ge in the channel from the adjacent SiGe layers. The profile 260 of the second channel layer 208a according to the present disclosure avoid the decreases near the surfaces.

Similarly in FIG. 2B, profile 264 schematically illustrates silicon concentration of the first channel layer 206a along the z-direction. Profile 266 schematically illustrates silicon concentration of an epitaxial SiGe channel layer formed between two epitaxial SiGe layers. Profile 268 schematically illustrates germanium concentration of the first channel layer 206a along the z-direction. Profile 270 schematically illustrates germanium concentration of an epitaxial SiGe channel layer formed between two epitaxial SiGe layers. As shown in profiles 264, 268, no silicon or germanium intermixing near the surfaces of the channel layer 206a according to the present disclosure.

In the semiconductor structure 200, the channel layers 206a for the P-FET and the channel layers 208a for the N-FET have the same crystalline orientation. In other embodiments of the present disclosure, the channel layers of the P-FET and N-FET may have different crystalline orientations, thus, optimizing hole mobilities without sacrificing electron mobilities.

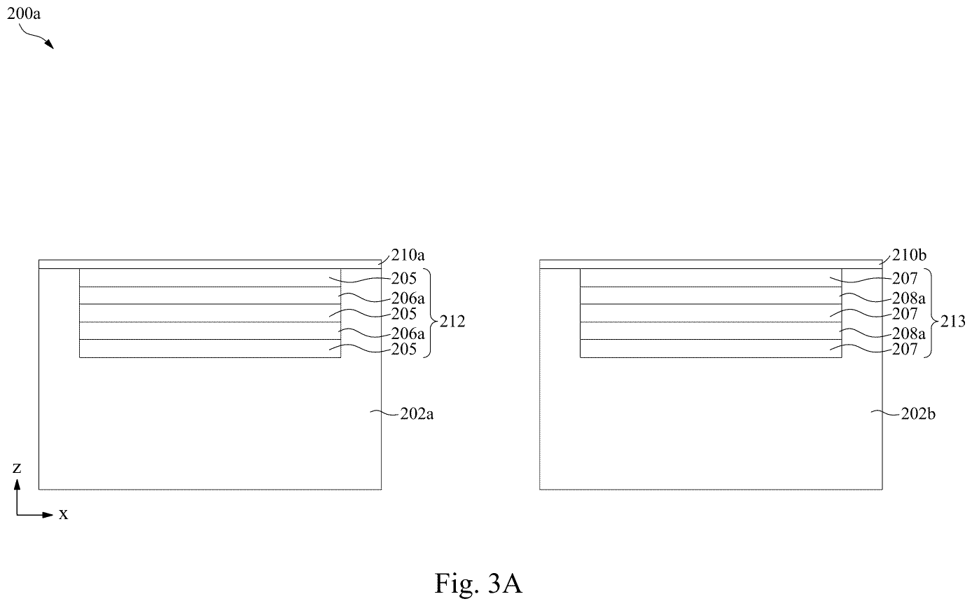

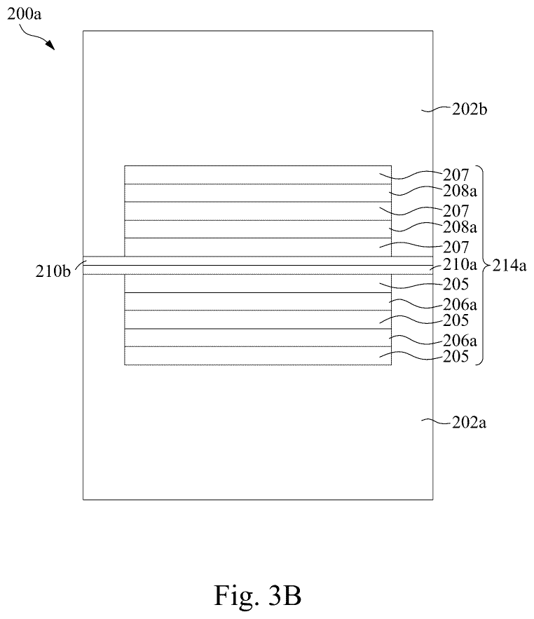

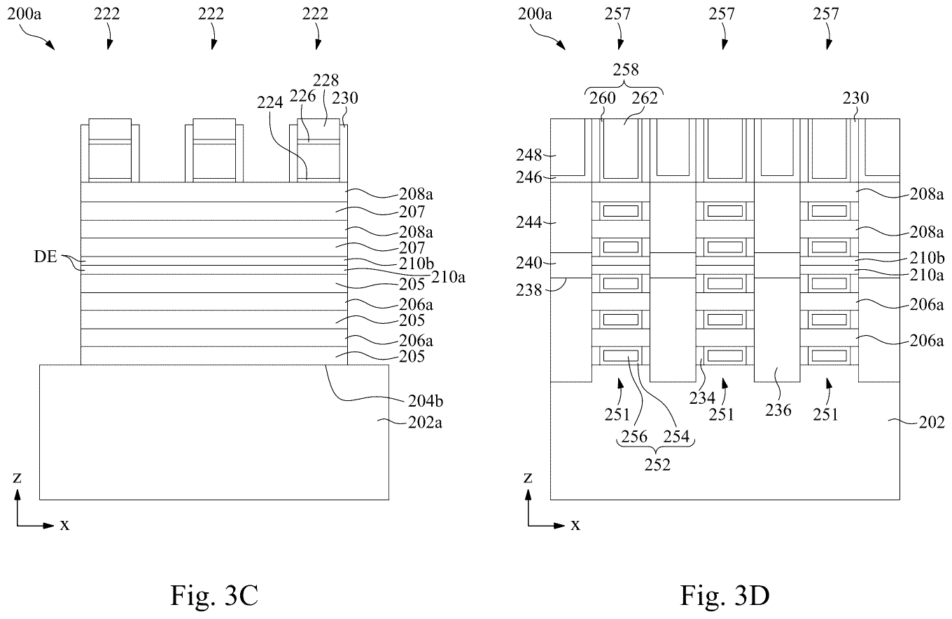

FIGS. 3A-3D schematically illustrate various stages of fabricating a semiconductor structure 200a having vertically stacked complementary field effect transistors (CFETs) according to some embodiments of the present disclosure.

In FIG. 3A, a first channel stack 212 including pairs of the first sacrificial layers 205 and the first channel layers 206a are formed on a first substrate 202a while a second channel stack 213 including pairs of the second sacrificial layers 207 and the second channel layers 208a are formed on a second substrate 202b. The first and second substrates 202a, 202b have different surface orientation. In some embodiments, the first substrate 202a has a (110) crystalline orientation and the second substrate 202b has a (100) crystalline orientation.

After formation of the stack of the first sacrificial layers 205 and the first channel layers 206a, a bonding layer 210a is deposited over the first substrate 202a. After formation of the stack of the second sacrificial layers 207 and the second channel layers 208a, a bonding layer 210bis deposited over the second substrate 202b. The bonding layers 210a, 210b may include one or more layer of suitable material to bond with the first and second sacrificial layers 205, 207 and provide isolation therebetween. In some embodiments, the bonding layer 210a, 210b includes one or more dielectric layers. For example, the bonding layer 210a, 210b may include silicon carbon-nitride (SiCN), silicon oxy-carbon-nitride (SiOCN), silicon oxide, silicon nitride, a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), compounds thereof, composites thereof, combinations thereof, or the like. The bonding layer 210a may be formed by a suitable deposition method, such as chemical vapor deposition (CVD), plasma-enhanced CVD (PECVD), spin-on, or the like.

In some embodiments, the bonding layers 210a, 210b may be symmetrically formed from the same material and substantially the same thickness. In other embodiments, the bonding layers 210a, 210b may be non-symmetrically formed, from different materials and/or different thicknesses, to achieve desired performance or processing efficiency.

In FIG. 3B, the first substrate 202a and the second substrate 202b are bonded together. The first and second substrates 202a, 202b may be bonded using suitable substrate bonding technology by joining the bonding layers 210a, 210b together.

In some embodiments, the first substrate 202a and the second substrate 202b may be bonded using a direct bonding process, such as dielectric-to-dielectric bonding. In some embodiments, surface cleaning is performed to remove particles, contaminations, and native oxides from surfaces of the first substrate 202a and the second substrate 202b. The surface cleaning process may include one or more cleaning methods, such as cryogenic cleaning, mechanical wiping and scrubbing, etching in a gas, plasma or liquid, ultrasonic and megasonic cleaning, laser cleaning, and the like.

In some embodiments, prior to performing the bonding operation, the first substrate 202a and the second substrate 202b may be positioned relative to each other so that intended channel orientations for in the first channel layers 206a and the second channel layers 208a are aligned with each other.

Subsequently, the bonding layers 210a, 210b of the first and second substrates 202a, 202b are put into physical contact under appropriate bonding pressures and temperatures to form a bonding structure 212 therebetween. A complementary channel stack 214a is formed. A thinning process is performed to remove portions of the second substrate 202b and expose the second channel layers 208a for subsequent processing.

As shown in FIGS. 3C and 3D, the semiconductor structure 200a with vertically stacked CFETs are formed. The vertically stacked transistors 251 and 251 have channel layers 206a, 208a with different crystalline orientations. In some embodiments, the channel layers 206a for the P-FET have a (110) crystalline orientation with improved hole mobility and the channel layers 208a for the N-FET have a (100) crystalline orientation with optimized electron mobility. Bonding layers 210a, 210b function as inter-transistor dielectric layer.

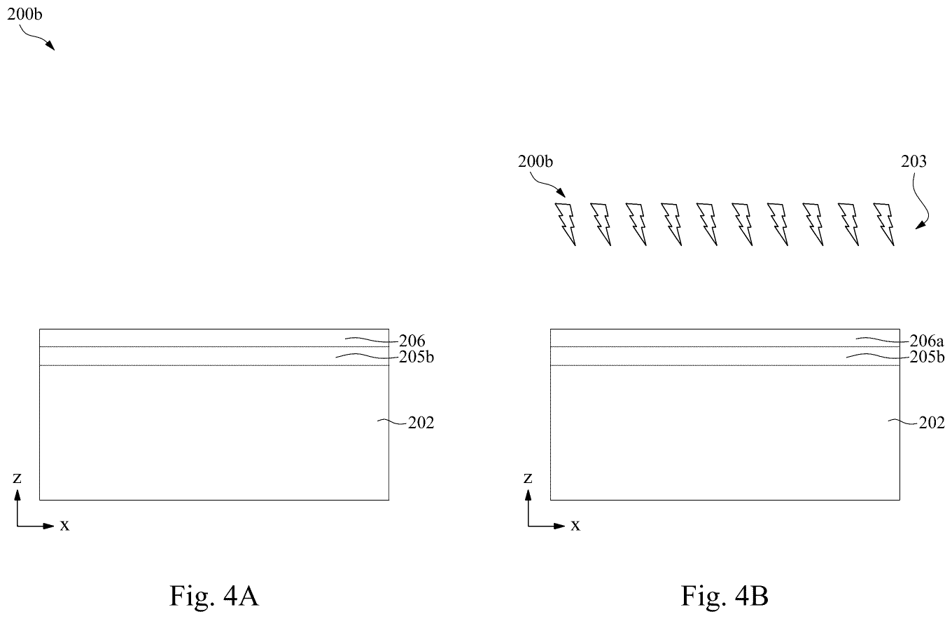

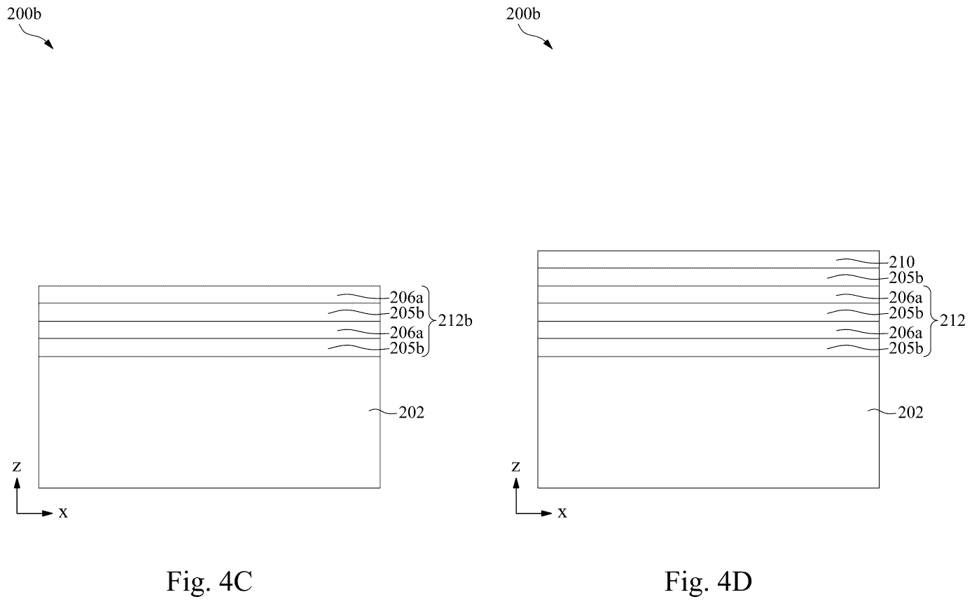

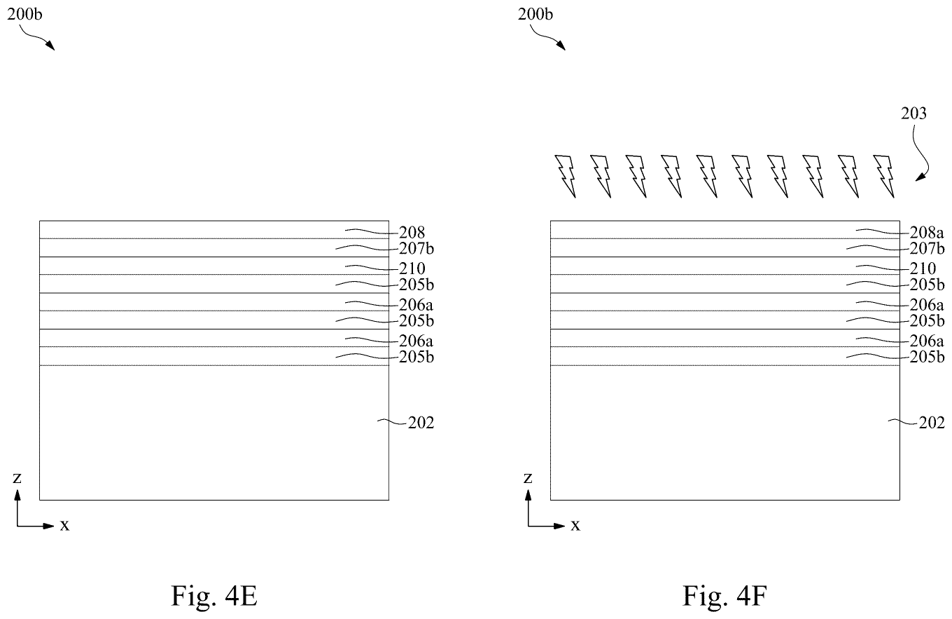

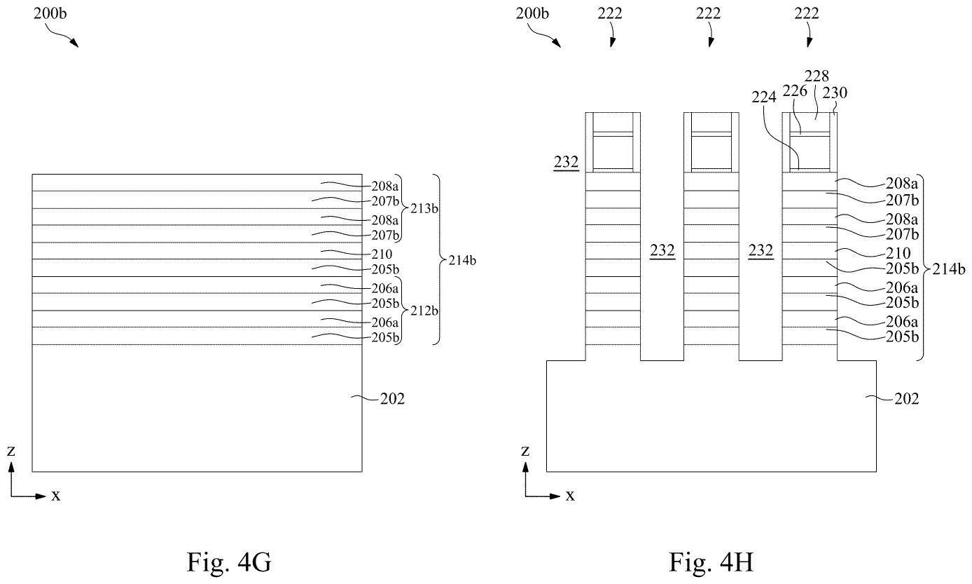

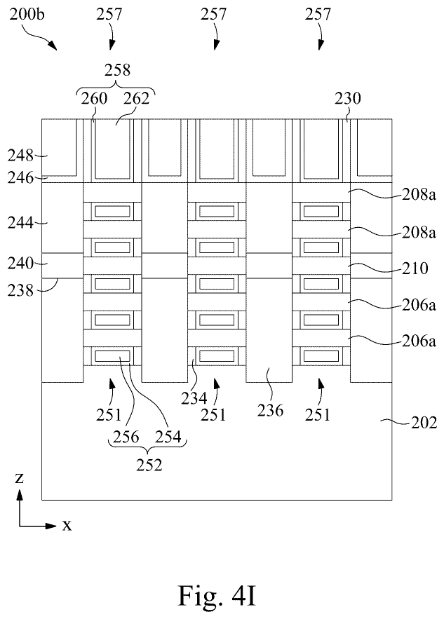

FIGS. 4A-4I schematically illustrate various stages of fabricating a semiconductor structure 200b having vertically stacked complementary field effect transistors (CFETs) according to some embodiments of the present disclosure. The semiconductor structure 200b includes a channel stack including sacrificial layers formed from perovskite oxides and channel layers recrystallized with the perovskite oxides as seed layers.

In FIG. 4A, a first sacrificial layer 205b is formed the substrate 202. In some embodiments, the first sacrificial layer 205b may include a perovskite oxide material. In some embodiments, the first sacrificial layer 205b may be a perovskite-type single crystal material having a chemical formula ABO₃, wherein A is a rare earth element including one or more of Sc, Y, La, Ce, Pr, Nd, Pm, Sm, Eu, Gd, Tb, Dy, Ho, Er, Tm, Yb, and Lu, or an alkaline earth element including one or more of Be, Mg, Ca, Sr, and Ba, and B is a non-rare earth element including one or more of Ti, Zr, Hf, Al, Ga, In, Tl, Ge, Sn, and Pb, or a rare-earth element or a transition metal. The first sacrificial layer 205b may be selected to have a crystalline orientation desirable for the channel layers 206a to be formed. In some embodiments, the first sacrificial layer 205b may be YAlO₃, LaAlO₃, SrTiO₃, or the like.

Further as shown in FIG. 4A, a first channel layer 206 is formed on the first sacrificial layer 205b. The first channel layer 206 includes semiconductor materials suitable to function as a channel layer. The first channel layer 206 include semiconductor materials, such as Si, SiGe, Ge, SiC, GeAs, GaP, InP, InAs, InSb, GaAsP, AlInAs, AlGaAs, InGaAs, GaInP, GaInAsP, or any combinations thereof. In some embodiments, the first channel layer 206 is made of SiGe, with Ge concentration in a range between about 15% and about 35%. The first channel layer 206 may be deposited in an amorphous form. The amorphous semiconductor deposition process may be carried out in a LPCVD reactor, in a temperature between about 360° C. to 560° C., for example about 400° C.

After formation of the amorphous first channel layer 206, a solid phase epitaxial recrystallization (SPER) process is performed to convert the first channel layer 206 to a crystalline state, as shown in FIG. 4B. In some embodiments, the SPER process is performed by a laser anneal process. In some embodiments, a laser source 203 is applied to the first channel layer 206 to rapidly raise the temperature of the first channel layer 206 to a temperature level between about 1200° C. to about 1400° C. In some embodiments, the laser source 203 may be pulsed for a short duration, for example for a duration in a range between about 100 ns and 500 ns, such as about 160 ns. By rapidly raise the temperature for a short duration, the first channel layer 206 is annealed to a crystalline state while still in the solid phase, annotated as the first channel layer 206a.

Because the first channel layer 206 is in contact with the perovskite structure of the first sacrificial layer 205b, the crystalline structure of first sacrificial layer 205b serves as seed layers for the recrystallization of the first channel layer 206a. Therefore, the crystalline orientation of the first channel layer 206a may be the same as the first sacrificial layer 205b.

Depending on the number of channels in the device structure, additional pairs of first sacrificial layer 205b and first channel layer 206a may be formed on the substrate 202, as shown in FIG. 4C. The same processes, i.e. deposition of a first sacrificial layer 205b, deposition of a first channel layer 206, and SPER recrystallization, may be repeated to form each pair of first sacrificial layer 205b and first channel layer 206a. Pairs of first sacrificial layer 205b and first channel layer 206a form a first channel stack 212b. In some embodiments, the pairs of first sacrificial layer 205b and first channel layer 206a are designated for a first type of FET, such as P-FET. The first channel layers 206a may have a (100) or (110) crystalline orientation.

In FIG. 4D, a first sacrificial layer 205b and an inter-transistor dielectric layer 210 are formed over the pairs of the first sacrificial layer 205b and first channel layer 206a. The inter-transistor dielectric layer 210 functions to isolate gate structure around the first channel layers 206a from the gate structure above.

After formation of the inter-transistor dielectric layer 210, two or more pairs of a second sacrificial layer 207b and a second channel layer 208 may be sequentially formed over the inter-transistor dielectric layer 210, as shown in FIGS. 4E and 4F.

In FIG. 4E, a second sacrificial layer 207b is formed on inter-transistor dielectric layer 210. In some embodiments, the second sacrificial layer 205b may be a perovskite-type single crystal material having a chemical formula ABO₃, wherein A is a rare earth element including one or more of Sc, Y, La, Ce, Pr, Nd, Pm, Sm, Eu, Gd, Tb, Dy, Ho, Er, Tm, Yb, and Lu, or an alkaline earth element including one or more of Be, Mg, Ca, Sr, and Ba, and B is a non-rare earth element including one or more of Ti, Zr, Hf, Al, Ga, In, Tl, Ge, Sn, and Pb, or a rare-earth element or a transition metal. The second sacrificial layer 207b may be selected to have a crystalline orientation desirable for the channel layers 208a to be formed. In some embodiments, the second sacrificial layer 207b may be YAlO₃, LaAlO₃, SrTiO_{3,}, or the like.

In some embodiments, the first sacrificial layer 205b and the second sacrificial layer 207b may include different materials or materials with different crystalline orientations. In other embodiments, the first sacrificial layer 205b and the second sacrificial layer 207b may include the same materials or have the same crystalline orientation.

A second channel layer 208 is formed on the second sacrificial layer 207b. The second channel layer 208 includes semiconductor materials suitable to function as a channel layer. In some embodiments, the second channel layer 208 has a thickness along the z-direction in a range between about 3 nm and about 15 nm. The second channel layer 208 include semiconductor materials, such as Si, SiGe, Ge, SiC, GeAs, GaP, InP, InAs, InSb, GaAsP, AlInAs, AlGaAs, InGaAs, GaInP, GaInAsP, or any combinations thereof. In some embodiments, the second channel layer 208 is made of silicon. The second channel layer 208 may be deposited in an amorphous form. The amorphous semiconductor deposition process may be carried out in a LPCVD reactor, in a temperature between about 360° C. to 560° C., for example about 400° C.

After formation of the amorphous second channel layer 208, a solid phase epitaxial recrystallization (SPER) process is performed to convert the second channel layer 208 to a crystalline state, as shown in FIG. 4F. In some embodiments, the SPER process is performed by a laser anneal process.

Because the second channel layer 208 is in contact with the perovskite structure of the second sacrificial layer 207b, the crystalline structure of second sacrificial layer 207b serves as seed layers for the recrystallization of the second channel layer 208a. Therefore, the crystalline orientation of the second channel layer 208a may be the same as the second sacrificial layer 207b. Additional pairs of the second sacrificial layer 207b and the second channel layer 208b may be subsequently formed. The same processes, i.e. deposition of a second sacrificial layer 207b, deposition of a second channel layer 208, and SPER recrystallization, may be repeated to form each pair of second sacrificial layer 205b and second channel layer 208a. Pairs of second sacrificial layer 207b and second channel layer 208a form a second channel stack 213b, as shown in FIG. 4G.

The first channel stack 212b, the inter-transistor dielectric layer 210, and the second channel stack 213b form a channel stack 214b, which is configured to be channel regions of vertically stacked CFETs. After formation of the channel stack 214b, fin structures 216 are formed from the channel stack 214b and the substrate 202 and the sacrificial gate structures 222 are formed over the fin structures 216 as shown in FIG. 4H.

Source/drain regions and replacement gate structures are subsequently formed resulting in the semiconductor structure 200b in FIG. 4I. The semiconductor structure 200b includes vertically stacked CFETs. The vertically stacked transistors 251 and 251 have channel layers 206a, 208a with different crystalline orientations. In some embodiments, the channel layers 206a for the P-FET have a (110) crystalline orientation with improved hole mobility and the channel layers 208a for the N-FET have a (100) crystalline orientation with optimized electron mobility.

Even though fabrication of vertically stacked CFETs is discussed above, embodiments of the present disclosure may be used to fabricate any multi-channel FETs.

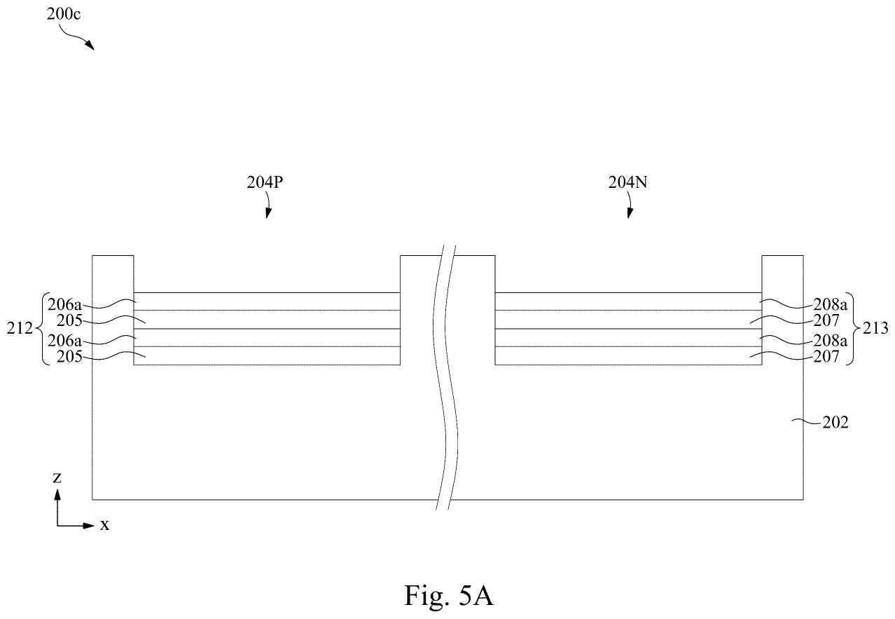

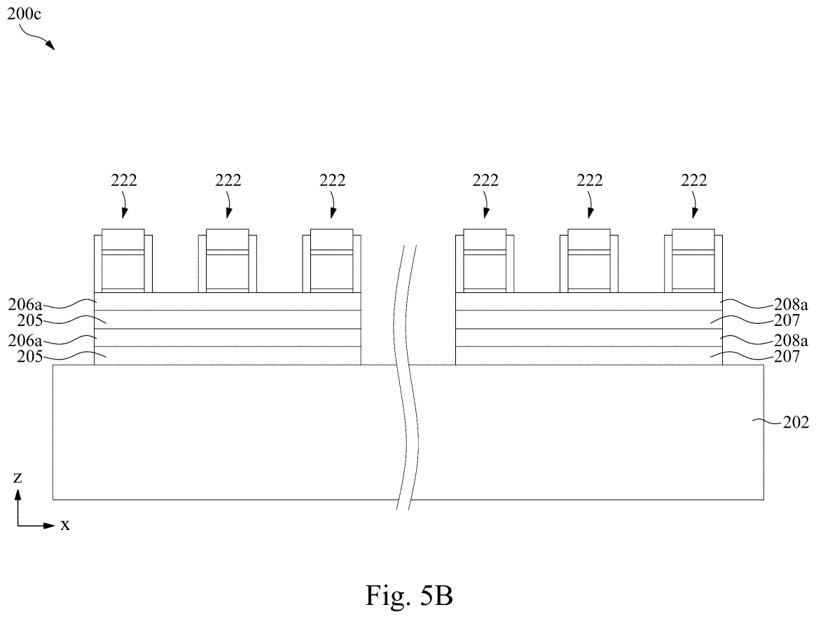

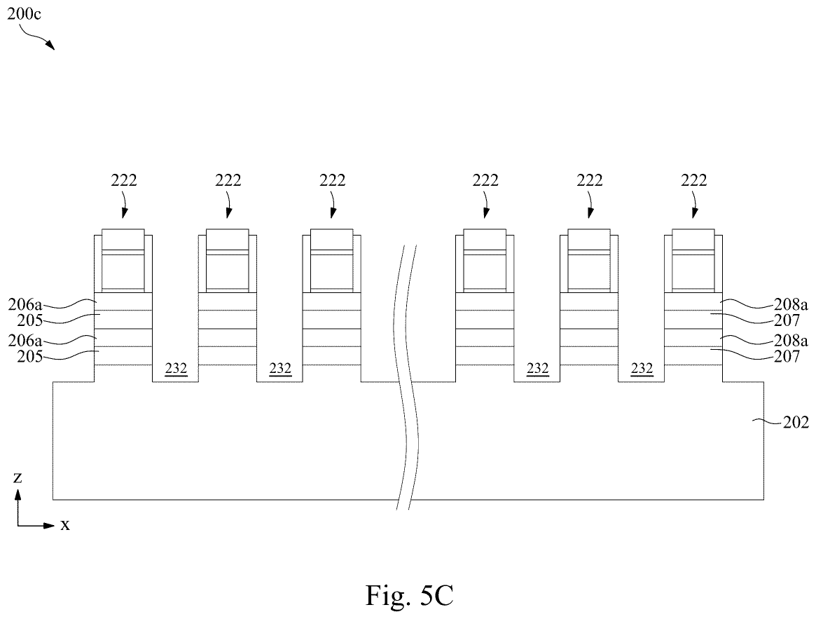

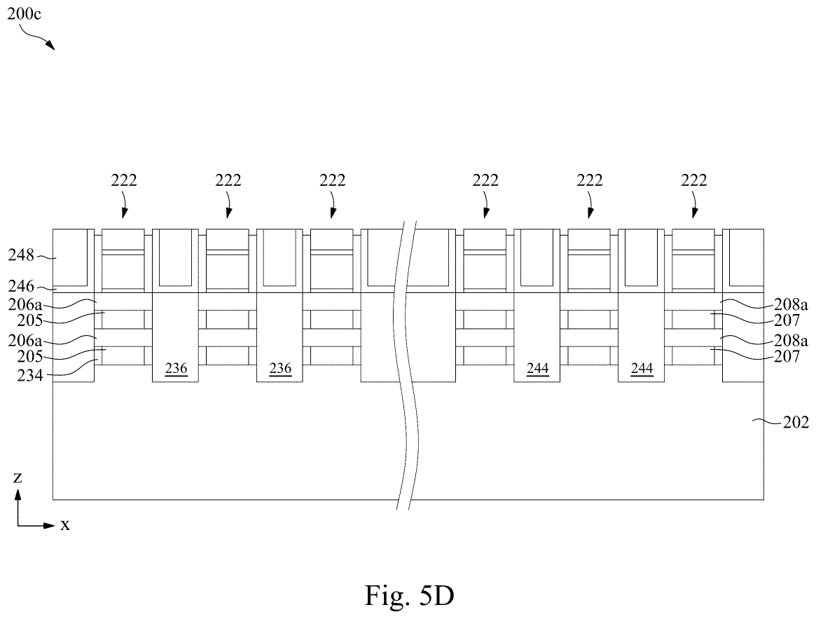

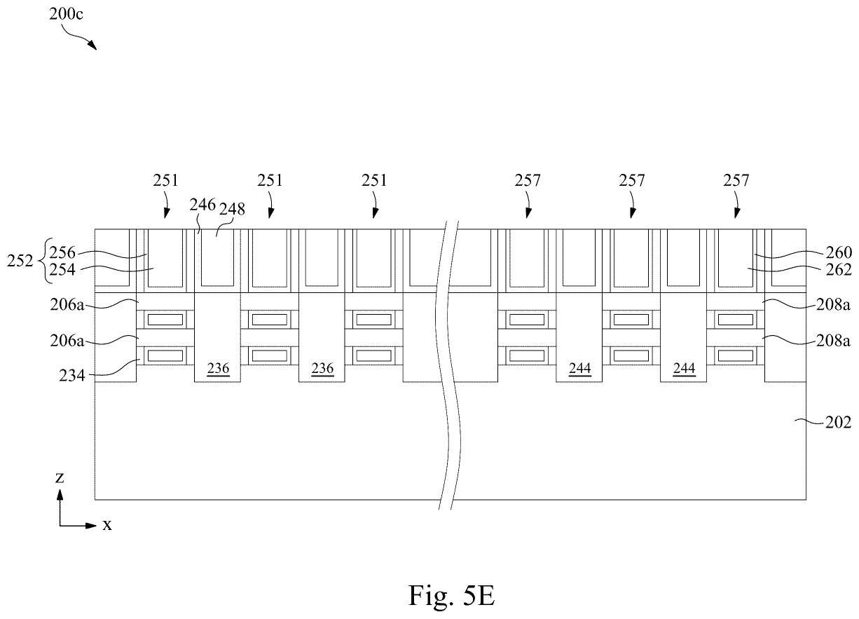

FIGS. 5A-5E schematically illustrate various stage of fabricating a semiconductor structure 200c with a gate-all-around field effect transistors according to embodiments of the present disclosure. The semiconductor structure 200c is fabricated by a similar process as the semiconductor structure 200 in FIGS. 1A-1P except that the N-FETs and P-FETS are disposed side-by-side instead of vertically stacked.

In FIG. 5A, stack cavities 204P and 204N are formed in different areas of the same substrate 202. Two or more pairs of the first sacrificial layer 205 and first channel layer 206a are formed in the stack cavity 204P and two or more pairs of the second sacrificial layer 207 and second channel layers 208a are formed in the stack cavity 204N. The first channel layers 206a and second channel layers 208a are first deposited in amorphous form and then recrystallized using the SPER process according to embodiments of the present disclosure. In some embodiments, first channel layers 206a and second channel layers 208a may be formed in separated processes using suitable masks. The first channel layers 206a and the second channel layers 208a have the same crystalline orientation.

In FIG. 5B, portions of the substrate 202 as the sidewalls 204s of the stack cavities 204P and 204N are removed, fin structures are formed from the channel stacks, and sacrificial gate structures 222 are formed over the fin structures.

In FIG. 5C, fin structures not covered by the sacrificial gate structures 222 are recessed to form source/drain recesses 232. In FIG. 5D, epitaxial source/drain regions 236 and 244 are grown from the first channel layers 206a and the second channel layers 208a respectively. In FIG. 5E, replacement gate processes are performed, and p-type transistors 251 and n-type transistors 257 are formed side-by-side on the substrate 202.

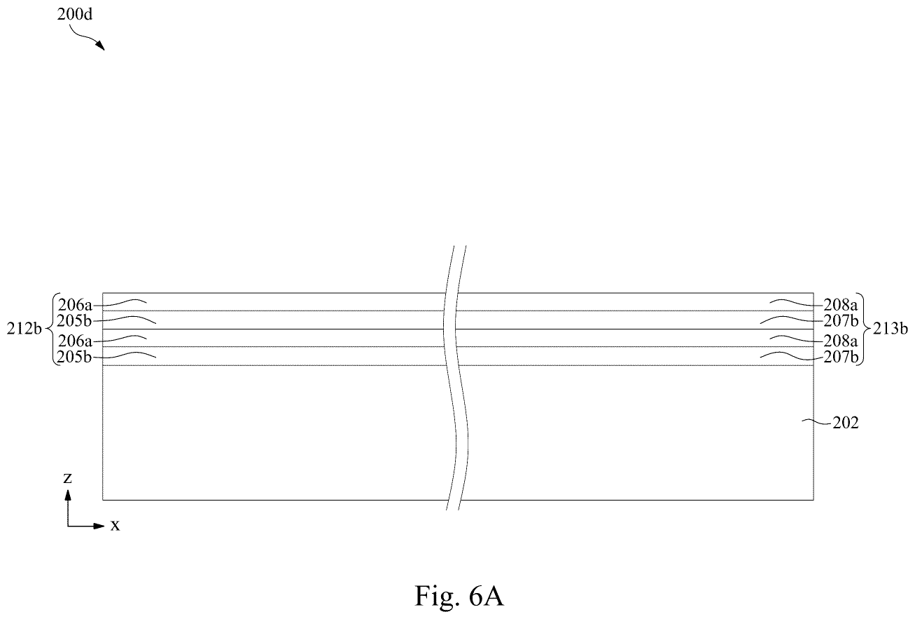

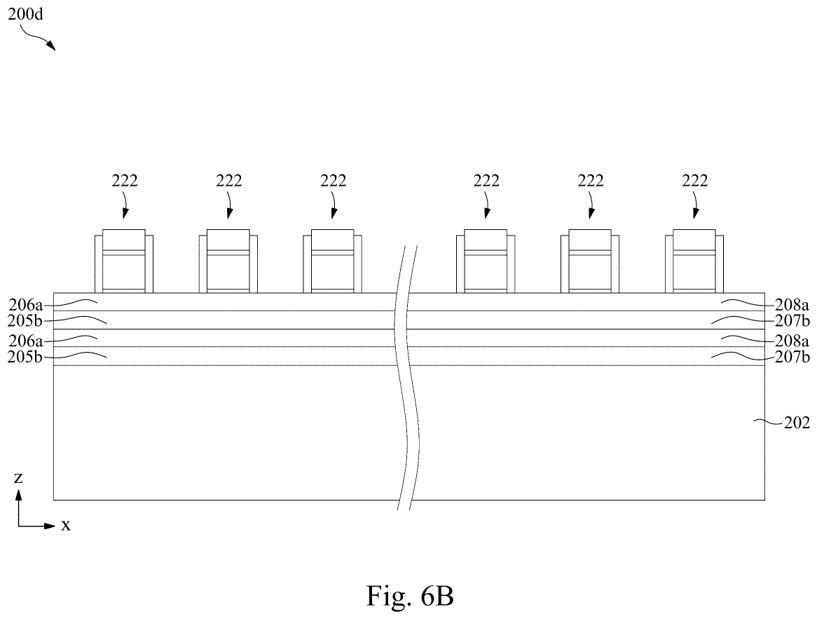

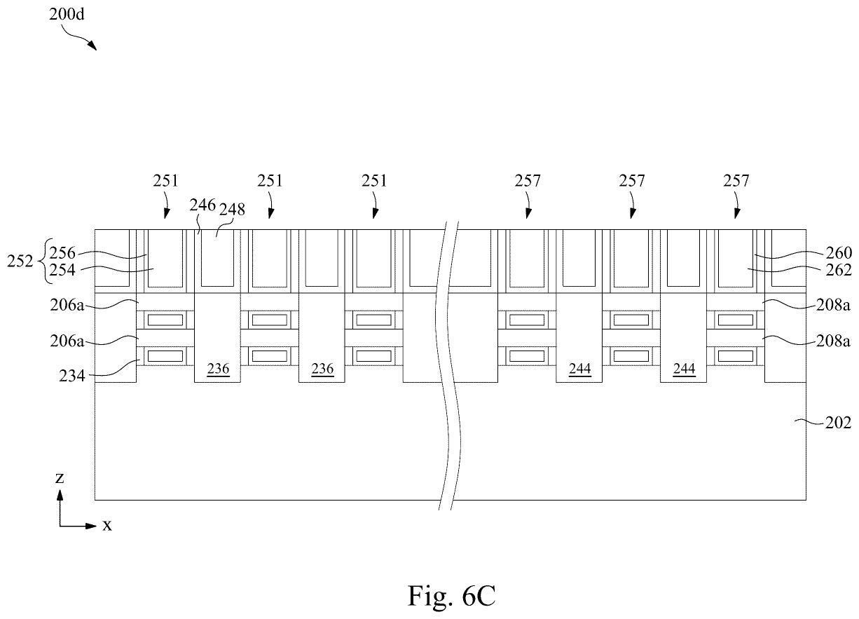

FIGS. 6A-6C schematically illustrate various stage of fabricating a semiconductor structure 200d with a gate-all-around field effect transistors according to embodiments of the present disclosure. The semiconductor structure 200d is fabricated by a similar process as the semiconductor structure 200b in FIGS. 4A-4I except that the N-FETs and P-FETS are disposed side-by-side instead of vertically stacked.

In FIG. 6A, two or more pairs of the first sacrificial layer 205b and first channel layer 206a and two or more pairs of the second sacrificial layer 207b and second channel layers 208a are formed side-by-side on different areas of the same substrate 202. The first channel layers 206a and second channel layers 208a are first deposited in amorphous form and then recrystallized using the SPER process according to embodiments of the present disclosure. In some embodiments, first channel layers 206a and second channel layers 208a may be formed in separated processes using suitable masks. Depending on the crystalline orientations of the first sacrificial layer 205b and the second sacrificial layer 207b, the first channel layers 206a and the second channel layers 208a have same crystalline orientation or different crystalline orientations.

In FIG. 6B, fin structures are formed from the channel stacks, and sacrificial gate structures 222 are formed over the fin structures. In FIG. 6C, epitaxial source/drain regions 236 and 244 are grown from the first channel layers 206a and the second channel layers 208a respectively. Replacement gate processes are performed, and p-type transistors 251 and n-type transistors 257 are formed side-by-side on the substrate 202.

Various embodiments or examples described herein offer multiple advantages over the state-of-art technology. By using laser recrystallization technology, the sacrificial layers in the channel stack may be oxide containing layers, instead of silicon and germanium containing epitaxial layer, i.e. SiGe sacrificial layers. By avoiding SiGe sacrificial layers, embodiments may reduce Ge segregation to adjacent semiconductor channel layers during thermal process. Embodiments of the present disclosure also reduces tensile strain caused by SiGe sacrificial layers to the Si channel layers. Additionally, embodiments of the present disclosure enable different crystalline orientations in p-channels and n-channels in the CFETs, therefore, improving device performance.

It will be understood that not all advantages have been necessarily discussed herein, no particular advantage is required for all embodiments or examples, and other embodiments or examples may offer different advantages.

Some embodiments of the present provide a method comprising: forming a first channel stack on a substrate, comprising: depositing a first sacrificial layer over the substrate; depositing a first channel layer on the first sacrificial layer, wherein the first channel layer is in an amorphous form; and crystallizing the first channel layer; patterning the first channel stack to form a fin structure over the substrate; and forming a first transistor from the fin structures, wherein the first transistor comprises first source/drain regions disposed across a portion of the first channel stack.

Some embodiments of the present disclosure provide a method comprising: depositing over a first sacrificial layer on a first substrate; depositing a first channel layer on the first sacrificial layer, wherein the first channel layer comprises a first semiconductor material in amorphous form; crystallizing the first channel layer in a first crystalline orientation by applying a pulsed laser energy to rapidly raise temperature of the first channel layer; depositing a second sacrificial layer; depositing a second channel layer on the second sacrificial layer, wherein the second channel layer comprises a second semiconductor material in amorphous form; crystallizing the second channel layer in a second crystalline orientation by applying a pulsed laser energy to rapidly raise temperature of the second channel layer; forming fin structures over the first channel layer and the second channel layer; forming first source/drain regions in contact with the first channel layer; and forming second source/drain regions in contact with the second channel layer.

Some embodiments of the present disclosure provide a semiconductor device, comprising: a first channel layer having a first crystalline orientation; a first gate dielectric layer surrounding the first channel layer; a first gate electrode layer disposed on the first gate dielectric layer; first source/drain regions in contact with the first channel layer; a second channel layer stacked over and aligned with the first channel layer, wherein the second channel layer having a second crystalline orientation; a second gate dielectric layer surrounding the second channel layer; a second gate electrode layer disposed on the second gate dielectric layer; second source/drain regions in contact with the second channel layer; and a dielectric layer disposed between the first gate dielectric layer and the second gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming a first channel stack on a substrate, comprising:
depositing a first sacrificial layer over the substrate;
depositing a first channel layer on the first sacrificial layer, wherein the first channel layer is in an amorphous form; and
crystallizing the first channel layer;
patterning the first channel stack to form a fin structure over the substrate; and
forming a first transistor from the fin structures, wherein the first transistor comprises first source/drain regions disposed across a portion of the first channel stack.

2. The method of claim 1, wherein crystallizing the first channel layer comprises:
applying a pulsed laser energy to rapidly raise temperature of the first channel layer.

3. The method of claim 2, wherein the first sacrificial layer comprises an oxide.

4. The method of claim 3, wherein the first sacrificial layer comprises a perovskite oxide.

5. The method of claim 2, wherein forming the first channel stack further comprises:
prior to depositing the first sacrificial layer, forming a stack cavity in the substrate, wherein the first sacrificial layer and the first channel layer are deposited in the stack cavity, and the first channel layer is in contact with sidewalls of the stack cavity.

6. The method of claim 2, further comprising:
forming a second channel stack, comprising:
depositing a second sacrificial layer over the substrate;
depositing a second channel layer on the second sacrificial layer, wherein the second channel layer is in an amorphous form; and
recrystallizing the second channel layer.

7. The method of claim 6, further comprising:
forming a dielectric layer over the first channel stack, wherein the second channel stack is disposed the dielectric layer and vertically stacked over the first channel stack.

8. The method of claim 6, wherein the second channel stack is formed on a second substrate, the method further comprising:
forming a first bonding film over the first channel stack;
forming a second bonding film over the second channel stack; and
bonding the first bonding film to the second bonding film so that the second channel stack is stacked over the first channel stack.

9. The method of claim 6, wherein the first channel stack and the second channel stack are formed side-by-side on the substrate.

10. The method of claim 6, wherein the first sacrificial layer comprises a first perovskite and the second sacrificial layer comprises a second perovskite oxide, and the first and second perovskite oxides have different crystalline orientation.

11. A method, comprising:
depositing over a first sacrificial layer on a first substrate;
depositing a first channel layer on the first sacrificial layer, wherein the first channel layer comprises a first semiconductor material in amorphous form;
crystallizing the first channel layer in a first crystalline orientation by applying a pulsed laser energy to rapidly raise temperature of the first channel layer;
depositing a second sacrificial layer;
depositing a second channel layer on the second sacrificial layer, wherein the second channel layer comprises a second semiconductor material in amorphous form;
crystallizing the second channel layer in a second crystalline orientation by applying a pulsed laser energy to rapidly raise temperature of the second channel layer;
forming fin structures over the first channel layer and the second channel layer;
forming first source/drain regions in contact with the first channel layer; and
forming second source/drain regions in contact with the second channel layer.

12. The claim of claim 11, wherein the first sacrificial layer comprises a first perovskite oxide having the first crystalline orientation, and the second sacrificial layer comprises a second perovskite oxide having the second crystalline orientation.

13. The method of claim 12, further comprising:
forming a dielectric layer over the first channel layer, wherein the second channel layer is disposed on the dielectric layer and vertically stacked over the first channel layer.

14. The method of claim 12, wherein the first channel layer and the second channel layer are formed side-by-side on different areas of the first substrate.

15. The method of claim 11, wherein the second sacrificial layer is disposed on a second substrate, the first substrate has the first crystalline orientation, and the second substrate has the second crystalline orientation, and the method further comprising:
forming a first bonding film over the first channel layer;
forming a second bonding film over the second channel layer;
bonding the first bonding film to the second bonding film so that the second channel layer is stacked over the first channel layer; and
removing the second substrate.

16. The method of claim 15, further comprising: prior depositing the first sacrificial layer on the first substrate,
forming a first stack cavity in the first substrate, wherein the first sacrificial layer and the first channel layer are deposited in the first stack cavity, and the first channel layer is in contact with sidewalls of the first stack cavity.

17. A semiconductor device, comprising:
a first channel layer having a first crystalline orientation;
a first gate dielectric layer surrounding the first channel layer;
a first gate electrode layer disposed on the first gate dielectric layer;
first source/drain regions in contact with the first channel layer;
a second channel layer stacked over and aligned with the first channel layer, wherein the second channel layer having a second crystalline orientation;
a second gate dielectric layer surrounding the second channel layer;
a second gate electrode layer disposed on the second gate dielectric layer;
second source/drain regions in contact with the second channel layer; and
a dielectric layer disposed between the first gate dielectric layer and the second gate dielectric layer.

18. The semiconductor device of claim 16, wherein the first channel layer and the second channel layer comprise crystalline semiconductor material formed by a solid-phase epitaxial recrystallization.

19. The semiconductor device of claim 18, wherein the first channel layer comprises SiGe.

20. The semiconductor device of claim 19, wherein the second channel layer comprises Si.
